(19) United States
(12) Patent Application Publication
(10) Pub. No.: US 2017/0221698 A1
(43) Pub. Date: Aug. 3, 2017

(54) METHOD OF MANUFACTURING SEMICONDUCTOR DEVICE, SUBSTRATE PROCESSING APPARATUS, AND RECORDING MEDIUM

(71) Applicant: HITACHI KOKUSAI ELECTRIC INC., Tokyo (JP)

(72) Inventors: Yoshitomo HASHIMOTO, Toyama-shi (JP); Yoshiro HIROSE, Toyama-shi (JP)

(73) Assignee: HITACHI KOKUSAI ELECTRIC INC., Tokyo (JP)

(21) Appl. No.: 15/421,162

(22) Filed: Jan. 31, 2017

(30) Foreign Application Priority Data
Feb. 1, 2016 (JP) 2016-017113

(51) Int. Cl. H01L 21/02; C23C 16/52; C23C 16/32; C23C 16/455; C23C 16/30; C23C 16/36

(52) U.S. Cl. CPC H01L 21/0228; H01L 21/0214; H01L 21/02167; C23C 16/308; C23C 16/36; C23C 16/325; C23C 16/45527; C23C 16/52; C23C 16/45544

(57) ABSTRACT

A semiconductor device manufacturing method includes forming a film having a desired composition on a substrate by selectively performing at least one of: performing, n₁ times, a cycle including processes of sequentially supplying a first precursor gas, a nitriding gas and an oxidizing gas to the substrate; performing, n₂ times, a cycle including processes of sequentially supplying the first precursor gas, the oxidizing gas and the nitriding gas to the substrate; performing, n₃ times, a cycle including processes of sequentially supplying a second precursor gas containing a chemical bond of a predetermined element and carbon, which is more than that contained in the first precursor gas, the nitriding gas and the oxidizing gas to the substrate; and performing, n₄ times, a cycle including processes of sequentially supplying the second precursor gas, the oxidizing gas and the nitriding gas to the substrate.

### CROSS-REFERENCE TO RELATED APPLICATION

This application is based upon and claims the benefit of priority from Japanese Patent Application No. 2016-017113, filed on Feb. 1, 2016, the entire contents of which are incorporated herein by reference.

### TECHNICAL FIELD

The present disclosure relates to a method of manufacturing a semiconductor device, a substrate processing apparatus, and a non-transitory computer-readable recording medium.

### BACKGROUND

As an example of many processes for manufacturing a semiconductor device, a process of supplying plural kinds of process gases onto a substrate to form a film on the substrate is often carried out.

### SUMMARY

The present disclosure provides some embodiments of a technique capable of improving the controllability of a composition ratio of a film formed on a substrate.

According to one embodiment of the present disclosure, there is provided a method of manufacturing a semiconductor device, which includes: forming a film having a desired composition on a substrate by selectively performing at least one of: (a) performing a cycle, n₁ times (n₁ being an integer of one or more), the cycle including performing in the following order: supplying a first precursor gas containing a chemical bond of a predetermined element and carbon to the substrate, supplying a nitriding gas to the substrate, and supplying an oxidizing gas to the substrate; (b) performing a cycle, n₂ times (n₂ being an integer of one or more), the cycle including performing in the following order: supplying the first precursor gas to the substrate, supplying an oxidizing gas to the substrate, and supplying a nitriding gas to the substrate; (c) performing a cycle, n₃ times (n₃ being an integer of one or more), the cycle including performing in the following order: supplying a second precursor gas containing a chemical bond of the predetermined element and carbon, which is more than the chemical bond of the predetermined element and carbon contained in the first precursor gas, to the substrate, supplying a nitriding gas to the substrate, and supplying an oxidizing gas to the substrate; and (d) performing a cycle, n₄ times (n₄ being an integer of one or more), the cycle including performing in the following order: supplying the second precursor gas to the substrate, supplying an oxidizing gas to the substrate, and supplying a nitriding gas to the substrate.

### BRIEF DESCRIPTION OF THE DRAWINGS

FIG. 1 is a schematic configuration view of a vertical processing furnace of a substrate processing apparatus suitably used in an embodiment of the present disclosure, in which a portion of the processing furnace is shown in a vertical cross section.

FIG. 2 is a schematic configuration view of the vertical processing furnace of the substrate processing apparatus suitably used in an embodiment of the present disclosure, in which a portion of the processing furnace is shown in a cross section taken along line A-A in FIG. 1.

FIG. 3 is a schematic configuration diagram of a controller of the substrate processing apparatus suitably used in an embodiment of the present disclosure, in which a control system of the controller is shown in a block diagram.

FIGS. 4A to 4D are diagrams illustrating film forming steps A to D, respectively, according to one embodiment of the present disclosure.

FIG. 5 is a diagram illustrating evaluation results of a composition ratio of a film formed on a substrate.

FIG. 6 is a diagram illustrating evaluation results of etching resistance of a film formed on a substrate.

FIG. 7 is a schematic configuration view of a processing furnace of a substrate processing apparatus suitably used in another embodiment of the present disclosure, in which a portion of the processing furnace is shown in a vertical cross section.

FIG. 8 is a schematic configuration view of a processing furnace of a substrate processing apparatus suitably used in another embodiment of the present disclosure, in which a portion of the processing furnace is shown in a vertical cross section.

### DETAILED DESCRIPTION

### One Embodiment of the Present Disclosure

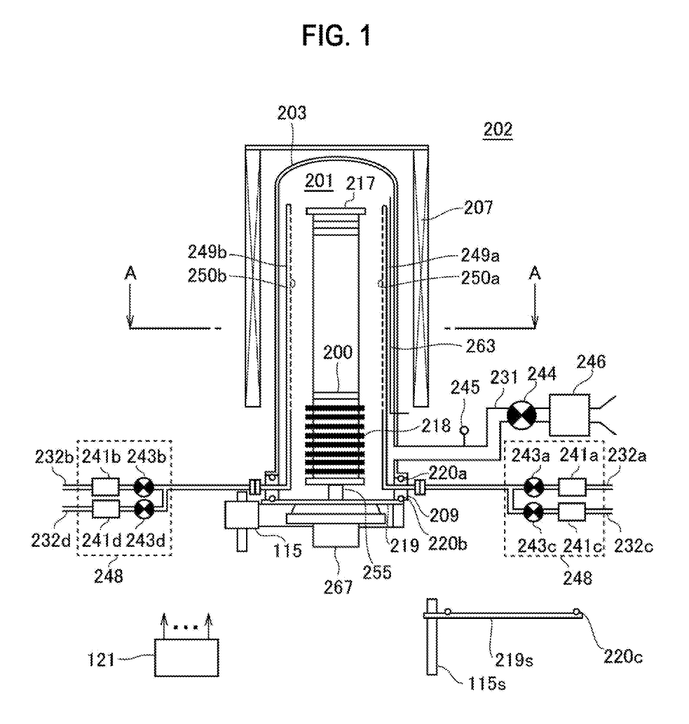

One embodiment of the present disclosure will now be described with reference to FIGS. 1 to 3.

### (1) Configuration of Substrate Processing Apparatus

As shown in FIG. 1, a processing furnace 202 includes a heater 207 as a heating mechanism (a temperature adjustment part). The heater 207 has a cylindrical shape and is supported by a support plate so as to be vertically installed. The heater 207 functions also as an activation mechanism (an excitation part) configured to thermally activate (excite) gas.

A reaction tube 203 is disposed inside the heater 207 in a concentric relationship with the heater 207. The reaction tube 203 is made of, e.g., a heat resistant material such as quartz (SiO₂), silicon carbide (SiC) or the like, and is formed in a cylindrical shape with its upper end closed and its lower end opened. A manifold (inlet flange) 209 is disposed in a concentric relationship with the reaction tube 203 under the reaction tube 203. The manifold 209 is made of, e.g., metal such as stainless steel (SUS) or the like and is formed in a cylindrical shape with upper and lower ends thereof opened. An upper end portion of the manifold 209 engages with a lower end portion of the reaction tube 203 so as to support the reaction tube 203. An O-ring 220a serving as a seal member is installed between the manifold 209 and the reaction tube 203. Like the heater 207, the reaction tube 203 is vertically installed. A process vessel (reaction vessel) is mainly constituted by the reaction tube 203 and the manifold 209. A process chamber 201 is formed in a hollow cylindrical portion of the process vessel. The process chamber 201 is configured to accommodate a plurality of wafers 200 as substrates.

Nozzles 249a and 249b are installed inside the process chamber 201 so as to penetrate through a sidewall of the manifold 209. Gas supply pipes 232a and 232b are respectively connected to the nozzles 249a and 249b.

Mass flow controllers (MFC) 241a and 241b used as flow rate controllers (flow rate control parts), and valves 243a and 243b used as opening/closing valves, are installed in the gas supply pipes 232a and 232b in this order from respective upstream sides, respectively. Gas supply pipes 232c and 232d, which supply an inert gas, are respectively connected to the gas supply pipes 232a and 232b at downstream sides of the valves 243a and 243b. MFCs 241c and 241d and valves 243c and 243d are installed in the gas supply pipes 232c and 232d in this order from respective upstream sides, respectively.

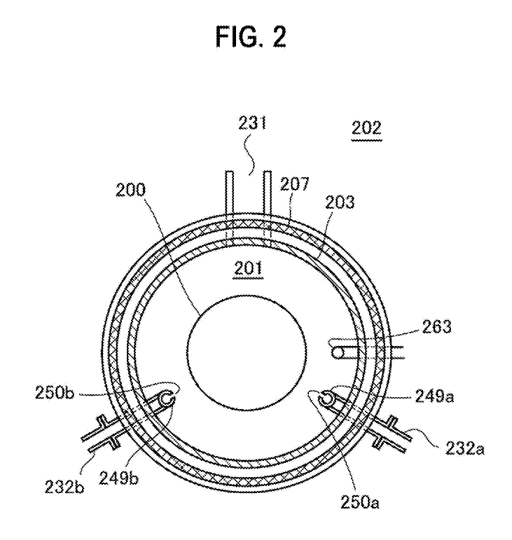

The nozzles 249a and 249b are respectively connected to front end portions of the gas supply pipes 232a and 232b. As shown in FIG. 2, each of the nozzles 249a and 249b is disposed in an annular space (when viewed from top) between the inner wall of the reaction tube 203 and the wafers 200 so as to extend upward along a stack direction of the wafers 200 from a lower portion of the inner wall of the reaction tube 203 to an upper portion thereof. Specifically, each of the nozzles 249a and 249b is installed in a region horizontally surrounding a wafer arrangement region in which the wafers 200 are arranged at a lateral side of the wafer arrangement region, along the wafer arrangement region. Each of the nozzles 249a and 249b is configured as an L-shaped nozzle. Gas supply holes 250a and 250b through which gas is supplied, are formed on the side surfaces of the nozzles 249a and 249b, respectively. Each of the gas supply holes 250a and 250b is opened toward the center of the reaction tube 203 to allow the gas to be supplied toward the wafers 200. The gas supply holes 250a and 250b may be formed at multiple locations between the lower portion of the reaction tube 203 and the upper portion thereof. The plurality of gas supply holes 250a and 250b may be formed to have the same opening area at the same opening pitch.

As described above, in this embodiment, a gas is transferred through the nozzles 249a and 249b, which are disposed in the vertically-elongated annular space (when viewed from top), i.e., a cylindrical space, defined by the inner surface of the side wall of the reaction tube 203 and the end portions (peripheral portions) of the wafers 200 arranged inside the reaction tube 203. The gas is initially injected into the reaction tube 203, near the wafers 200, through the gas supply holes 250a and 250b formed respectively in the nozzles 249a and 249b. Accordingly, the gas supplied into the reaction tube 203 mainly flows in the reaction tube 203 in a direction parallel to surfaces of the wafers 200, i.e., in a horizontal direction. With this configuration, the gas can be uniformly supplied to the respective wafers 200. The gas flowing on the surfaces of the wafers 200 flows toward an exhaust port, i.e., an exhaust pipe 231 which will be described later. The flow direction of the gas is not limited to a vertical direction but may be appropriately varied depending on a position of the exhaust port.

Precursor gases (first precursor gas and second precursor gas) having a chemical bond (Si—C bond) of silicon (Si) and carbon (C) as predetermined elements (main elements), for example, a silane precursor gas containing a C-containing ligand, is supplied from the gas supply pipe 232a into the process chamber 201 via the MFC 241a, the valve 243a and the nozzle 249a.

The precursor gas refers to a gaseous precursor, for example, a gas obtained by vaporizing a precursor which remains in a liquid state under room temperature and atmospheric pressure, or a precursor which remains in a gas state under room temperature and atmospheric pressure. An example of the silane precursor containing a C-containing ligand may include an alkylhalosilane precursor or an alkylenehalosilane precursor. The alkylhalosilane precursor refers to a silane precursor having an alkyl ligand (alkyl group) and a halogen ligand (halogen group), and the alkylenehalosilane precursor refers to a silane precursor having an alkylene ligand (alkylene group) and a halogen ligand (halogen group).

An example of the alkyl ligand (alkyl group) may include a methyl ligand (methyl group), an ethyl ligand (ethyl group), a propyl ligand (propyl group), an isopropyl ligand (isopropyl group), a butyl ligand (butyl group), an isobutyl ligand (isobutyl group) or the like.

An example of the alkylene ligand (alkylene group) may include a methylene ligand (methylene group), an ethylene ligand (ethylene group), a propylene ligand (propylene group), a butylene ligand (butylene group) or the like.

An example of the halogen ligand (halogen group) may include a chloro ligand (chloro group), a fluoro ligand (fluoro group), a bromo ligand (bromo group) or an iodine ligand (iodine group). That is to say, the halogen ligand contains a halogen element such as chlorine (Cl), fluorine (F), bromine (Br) or iodine (I).

An example of the alkylhalosilane precursor gas may include a 1,1,2,2-tetrachloro-1,2-dimethyldisilane ((CH₃)₂Si₂Cl₄, abbreviation: TCDMDS) gas, a 1,2-dichloro-1,1,2,2-tetramethyldisilane ((CH₃)₄Si₂Cl₂, abbreviation: DCTMDS) gas, a 1-monochloro-1,1,2,2,2-pentamethyldisilane ((CH₃)₅Si₂Cl, abbreviation: MCPMDS) gas or the like. Each of these gases may refer to a precursor gas containing at least two Si atoms in one molecule, further containing C and Cl, and having a Si—C bond. The TCDMDS gas contains two Si—C bonds in one molecule, the DCTMDS gas contains four Si—C bonds in one molecule and the MCPMDS gas contains five Si—C bonds in one molecule. Each of these gases also has a Si—Si bond. Each of these gases act as a Si source or a C source in a film forming process to be described later.

An example of the alkylenehalosilane precursor gas may include a bis(trichlorosilyl)methane ((SiCl₃)₂CH₂, abbreviation: BTCSM) gas, an ethylenebis(trichlorosilane) gas, namely a 1,2-bis(trichlorosilyl)ethane ((SiCl₃)₂C₂H₄, abbreviation: BTCSE) gas, or the like. Each of these gases may refer to a precursor gas containing at least two Si atoms in one molecule, further containing C and Cl, and having a Si—C bond (Si—C—Si bond or Si—C—C—Si bond). Each of these gases act as a Si source or a C source in a film forming process to be described later.

It is possible to supply the precursor gases (the first precursor gas and the second precursor gas) from the gas supply pipe 232a independently at a predetermined timing. For example, from the gas supply pipe 232a, the TCDMDS gas may be supplied as the first precursor gas and the DCTMDS gas may be supplied as the second precursor gas. The DCTMDS gas contains Si—C bonds more than Si—C bonds contained in the TCDMDS gas. That is to say, each of the TCDMDS gas and the DCTMDS gas has an alkyl ligand (methyl group). The number of the methyl groups contained in the DCTMDS gas is larger than the number of the methyl groups contained in the TCDMDS gas.

A first reaction gas (reactant) differing in chemical structure (molecular structure) from the precursor gases, for example, a nitrogen (N)-containing gas, is supplied from the gas supply pipe 232b into the process chamber 201 via the MFC 241b, the valve 243b and the nozzle 249b. The N-containing gas acts as a nitriding gas, namely an N source, in a film forming process to be described later. An example of the nitriding gas may include an ammonia (NH₃) gas.

A second reaction gas (reactant) differing in chemical structure (molecular structure) from the precursor gases, for example, an oxygen (O)-containing gas, is supplied from the gas supply pipe 232b into the process chamber 201 via the MFC 241b, the valve 243b and the nozzle 249b. The O-containing gas acts as an oxidizing gas, namely an O source, in a film forming process to be described later. An example of the oxidizing gas may include an oxygen (O₂) gas.

An inert gas, for example, a nitrogen (N₂) gas, is supplied from the gas supply pipes 232c and 232d into the process chamber 201 via the MFCs 241c and 241d, the valves 243c and 243d, the gas supply pipes 232a and 232b and the nozzles 249a and 249b, respectively.

A precursor gas supply system for supplying the precursor gases (the first precursor gas and the second precursor gas) is mainly configured by the combination of the gas supply pipe 232a, the MFC 241a and the valve 243a. A nitriding gas supply system for supplying the nitriding gas is mainly configured by the combination of the gas supply pipe 232b, the MFC 241b and the valve 243b. An oxidizing gas supply system for supplying the oxidizing gas is mainly configured by the combination of the gas supply pipe 232b, the MFC 241b and the valve 243c. An inert gas supply system is mainly configured by the combination of the gas supply pipes 232c and 232d, the MFCs 241c and 241d and the valves 243c and 243d.

One or all of the above-described various supply systems may be configured as an integrated type gas supply system 248 in which the valves 243a to 243d, the MFCs 241a to 241d and so on are integrated. The integrated type gas supply system 248 is connected to each of the gas supply pipes 232a to 232d and is configured such that operations of supply of various gases into the gas supply pipes 232a to 232d, namely an opening/closing operation of the valves 243a to 243d, a flow rate adjustment operation performed by the MFCs 241a to 241d, and the like, are controlled by a controller 121 which will be described later. The integrated type gas supply system 248 is configured as an integral type or division type integrated unit, and may be attached to and detached from the gas supply pipes 232a to 232d and the like on an integrated unit basis, so that the maintenance, replacement or expansion of the gas supply system can be performed on an integrated unit basis.

An exhaust pipe 231 for exhausting an internal atmosphere of the process chamber 201 is installed inside the reaction tube 203. A vacuum pump 246 as a vacuum exhaust device is coupled to the exhaust pipe 231 via a pressure sensor 245, which is a pressure detector (pressure detecting part) for detecting an internal pressure of the process chamber 201, and an auto pressure controller (APC) valve 244, which is a pressure regulator (pressure regulating part). The APC valve 244 is configured to initiate or stop an evacuation operation with respect to the process chamber 201 by opening or closing the valve while the vacuum pump 246 is actuated. Further, the APC valve 244 is configured to regulate the internal pressure of the process chamber 201 by adjusting an opening degree of the valve based on a pressure information detected by the pressure sensor 245 while the vacuum pump 246 is actuated. An exhaust system is mainly configured by the combination of the exhaust pipe 231, the APC valve 244 and the pressure sensor 245. The vacuum pump 246 may be included in the exhaust system.

A seal cap 219, which serves as a furnace opening cover configured to hermetically seal a lower end opening of the manifold 209, is installed under the manifold 209. The seal cap 219 is made of metal such as, e.g., stainless steel (SUS) or the like, and is formed in a disc shape. An O-ring 220b, which is a seal member making contact with the lower end portion of the manifold 209, is installed on an upper surface of the seal cap 219. A rotation mechanism 267 configured to rotate a boat 217, which will be described later, is installed under the seal cap 219. A rotary shaft 255 of the rotation mechanism 267, which penetrates through the seal cap 219, is connected to the boat 217. The rotation mechanism 267 is configured to rotate the wafers 200 by rotating the boat 217. The seal cap 219 is configured to be vertically moved up and down by a boat elevator 115 which is an elevator mechanism installed outside the reaction tube 203. The boat elevator 115 is configured to load and unload the boat 217 into and from the process chamber 201 by moving the seal cap 219 up and down. The boat elevator 115 is configured as a transfer device (transfer mechanism) which transfers the boat 217, i.e., the wafers 200, into and out of the process chamber 201. In addition, a shutter 219s, which serves as a furnace opening cover configured to hermetically seal a lower end opening of the manifold 209 while the seal cap 219 is lowered by the boat elevator 115, is installed under the manifold 209. The shutter 219s is made of metal such as, e.g., stainless steel (SUS) or the like, and is formed in a disc shape. An O-ring 220c, which is a seal member making contact with the lower end portion of the manifold 209, is installed on an upper surface of the shutter 219s. The opening/closing operation (such as elevation operation, rotation operation or the like) of the shutter 219s is controlled by a shutter opening/closing mechanism 115s.

The boat 217 serving as a substrate support is configured to support the plurality of, e.g., 25 to 200 wafers 200 in such a state that the wafers 200 are arranged in a horizontal posture and in multiple stages along a vertical direction with the centers of the wafers 200 aligned with one another. That is to say, the boat 217 is configured to arrange the wafers 200 in a spaced-apart relationship. The boat 217 is made of a heat resistant material such as quartz or SiC. Heat insulating plates 218 made of a heat resistant material such as quartz or SiC are installed below the boat 217 in multiple stages. With this configuration, it is hard for heat generated from the heater 207 to be radiated to the seal cap 219. Instead of installing the heat insulating plates 218, a heat insulating tube as a tubular member made of a heat resistant material such as quartz or SiC may be installed.

A temperature sensor 263 serving as a temperature detector is installed inside the reaction tube 203. Based on temperature information detected by the temperature sensor 263, a state of supplying electric power to the heater 207 is adjusted such that the interior of the process chamber 201 has a desired temperature distribution. Similar to the nozzles 249a and 249b, the temperature sensor 263 is formed in an L-shape. The temperature sensor 263 is installed along the inner wall of the reaction tube 203.

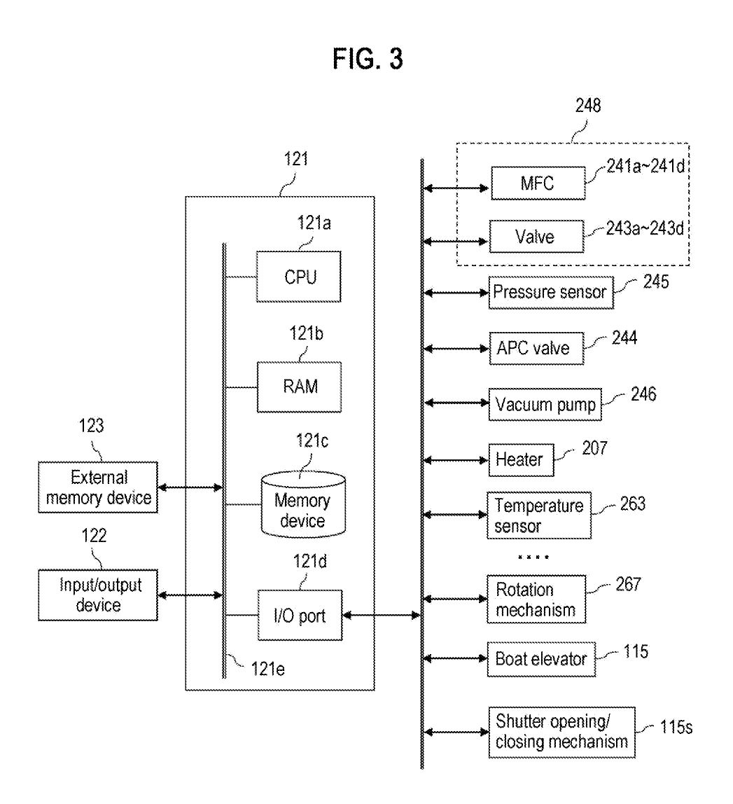

As illustrated in FIG. 3, the controller 121 as a control part (control unit) may be configured as a computer including a central processing unit (CPU) 121a, a random access memory (RAM) 121b, a memory device 121c and an I/O port 121d. The RAM 121b, the memory device 121c and the I/O port 121d are configured to exchange data with the CPU 121a via an internal bus 121e. An input/output device 122 formed of, e.g., a touch panel or the like, is connected to the controller 121.

The memory device 121c is configured with, for example, a flash memory, a hard disc drive (HDD) or the like. A control program for controlling operations of a substrate processing apparatus and a process recipe in which sequences and conditions of a film forming process to be described later are written, are readably stored in the memory device 121c. The process recipe functions as a program for causing the controller 121 to execute each sequence in the film forming process (to be described later) to obtain a predetermined result. Hereinafter, the process recipe and the control program will be generally simply referred to as a “program.” Furthermore, the process recipe will be simply referred to as a “recipe.” When the term “program” is used herein, it may indicate a case of including only the recipe, a case of including only the control program, or a case of including both the recipe and the control program. In addition, the RAM 121b is configured as a memory area (work area) in which a program or data read by the CPU 121a is temporarily stored.

The I/O port 121d is connected to the MFCs 241a to 241d, the valves 243a to 243d, the pressure sensor 245, the APC valve 244, the vacuum pump 246, the temperature sensor 263, the heater 207, the rotation mechanism 267, the boat elevator 115, the shutter opening/closing mechanism 115s and the like.

The CPU 121a is configured to read and execute the control program from the memory device 121c. The CPU 121a also reads the recipe from the memory device 121c according to an operation command inputted from the input/output device 122. In addition, the CPU 121a is configured to control the flow rate adjusting operation of various kinds of gases performed by the MFCs 241a to 241d, the opening/closing operation of the valves 243a to 243d, the opening/closing operation of the APC valve 244, the pressure regulating operation performed by the APC valve 244 based on the pressure sensor 245, the driving and stopping operation of the vacuum pump 246, the temperature adjusting operation performed by the heater 207 based on the temperature sensor 263, the operation of rotating the boat 217 with the rotation mechanism 267 and adjusting the rotation speed of the boat 217, the operation of moving the boat 217 up and down with the boat elevator 115, the opening/closing operation of the shutter 219s with the shutter opening/closing mechanism 115s, and the like, according to contents of the read recipe.

The controller 121 may be configured by installing, on the computer, the aforementioned program stored in an external memory device 123 (for example, a magnetic disc such as a hard disc, an optical disc such as a CD or DVD, a magneto-optical disc such as an MO, a semiconductor memory such as a USB memory). The memory device 121c or the external memory device 123 is configured as a non-transitory computer-readable recording medium. Hereinafter, the memory device 121c and the external memory device 123 will be generally simply referred to as a “recording medium.” When the term “recording medium” is used herein, it may indicate a case of including only the memory device 121c, a case of including only the external memory device 123, or a case of including both the memory device 121c and the external memory device 123. Furthermore, the program may be supplied to the computer using communication means such as the Internet or a dedicated line, instead of using the external memory device 123.

### (2) Film Forming Process

A sequence example of forming a thin film on a substrate using the aforementioned substrate processing apparatus, which is one of the processes for manufacturing a semiconductor device, will be described below. In the following descriptions, the operations of the respective parts constituting the substrate processing apparatus are controlled by the controller 121.

In this embodiment, as a film having a desired composition, a silicon oxycarbonitride film (SiOCN film) containing Si, O, C and N, or a silicon oxynitride film (SiON film) containing Si, O and N is formed on a wafer 200 by selectively performing one of:

a film forming step A of performing, n₁ times (n₁ being an integer of one or more), a cycle including a step of supplying a TCDMDS gas as a first precursor gas to the wafer 200 as a substrate, a step of supplying an NH₃ gas as a nitriding gas to the wafer 200, and a step of supplying an O₂ gas as an oxidizing gas to the wafer 200 in this order;

a film forming step B of performing, n₂ times (n₂ being an integer of one or more), a cycle including a step of supplying a TCDMDS gas to the wafer 200, a step of supplying an O₂ gas to the wafer 200, and a step of supplying an NH₃ gas to the wafer 200 in this order;

a film forming step C of performing, n₃ times (n₃ being an integer of one or more), a cycle including a step of supplying a DCTMDS gas as a second precursor gas which contains more Si—C bonds than Si—C bonds contained in a TCDMDS, to the wafer 200, a step of supplying an NH₃ gas to the wafer 200, and a step of supplying an O₂ gas to the wafer 200 in this order; and

a film forming step D of performing, n₄ times (n₄ being an integer of one or more), a cycle including a step of supplying a DCTMDS gas to the wafer 200, a step of supplying an O₂ gas to the wafer 200, and a step of supplying an NH₃ gas to the wafer 200 in this order.

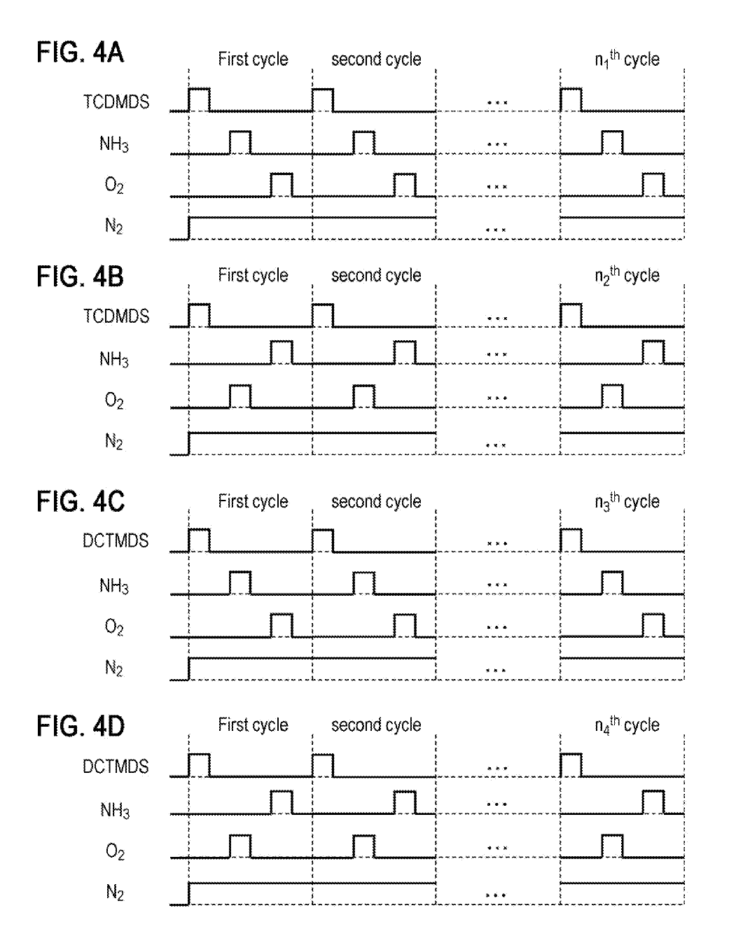

FIGS. 4A to 4D illustrate gas supply sequences in the film forming steps A to D, respectively. In the present disclosure, for the sake of convenience, the gas supply sequences in the film forming steps A to D may sometimes be denoted as follows or by symbols [a] to [d]. The same denotation will be used in modifications to be described later.

(TCDMDS→NH₃→O₂)×n₁ [a]

(TCDMDS→O₂→NH₃)×n₂ [b]

(DCTMDS→NH₃→O₂)×n₃ [c]

(DCTMDS→O₂→NH₃)×n₄ [d]

When the term “wafer” is used in the present disclosure, it may refer to “a wafer itself” or “a wafer and a laminated body (aggregate) of predetermined layers or films formed on a surface of the wafer.” That is to say, a wafer including predetermined layers or films formed on its surface may be referred to as a wafer. In addition, when the phrase “a surface of a wafer” is used in the present disclosure, it may refer to “a surface (exposed surface) of a wafer itself” or “a surface of a predetermined layer or film formed on a wafer, namely, an uppermost surface of the wafer as a laminated body.”

Accordingly, in the present disclosure, the expression “a predetermined gas is supplied to a wafer” may mean that “a predetermined gas is directly supplied to a surface (exposed surface) of a wafer itself” or that “a predetermined gas is supplied to a layer or film formed on a wafer, namely, to an uppermost surface of a wafer as a laminated body.” Furthermore, in the present disclosure, the expression “a predetermined layer (or film) is formed on a wafer” may mean that “a predetermined layer (or film) is directly formed on a surface (exposed surface) of a wafer itself” or that “a predetermined layer (or film) is formed on a layer or film formed on a wafer, namely, to an uppermost surface of a wafer as a laminated body.”

In addition, when the term “substrate” is used in the present disclosure, it may be synonymous with the term “wafer.”

### (Wafer Charging and Boat Loading)

When the plurality of wafers 200 is charged on the boat 217 (wafer charging), the shutter 219s is moved by the shutter opening/closing mechanism 115s so that the lower end opening of the manifold 209 is opened (shutter open). Thereafter, as illustrated in FIG. 1, the boat 217 supporting the plurality of wafers 200 is lifted up by the boat elevator 115 to be loaded into the process chamber 201 (boat loading). In this state, the seal cap 219 seals the lower end of the manifold 209 through the O-ring 220b.

### (Pressure and Temperature Adjusting Step)

The interior of the process chamber 201, namely, a space in which the wafers 200 exist, is evacuated (depressurization-exhausted) by the vacuum pump 246 such that the interior of the process chamber 201 has a desired pressure (degree of vacuum). In this operation, the internal pressure of the process chamber 201 is measured by the pressure sensor 245. The APC valve 244 is feedback-controlled based on the measured pressure information. The vacuum pump 246 may be continuously activated at least until the process of the wafers 200 is completed. The wafers 200 in the process chamber 201 are heated by the heater 207 to a desired film formation temperature. In this operation, the state of supplying electric power to the heater 207 is feedback-controlled based on the temperature information detected by the temperature sensor 263 such that the interior of the process chamber 201 has a desired temperature distribution. In addition, the heating of the interior of the process chamber 201 by the heater 207 may be continuously performed at least until the process of the wafers 200 is completed. The rotation of the boat 217 and the wafers 200 by the rotation mechanism 267 begins. The rotation of the boat 217 and the wafers 200 by the rotation mechanism 267 may be continuously performed at least until the process of the wafers 200 is completed.

### (Film Forming Step)

Subsequently, one of the above-mentioned film forming steps A to D is selectively performed. That is to say, a program A for executing a procedure of the film forming step A, a program B for executing a procedure of the film forming step B, a program C for executing a procedure of the film forming step C, and a program D for executing a procedure of the film forming step D are stored in advance in the external storage device 123. The CPU 121 selectively executes at least one of the programs A to D. The respective process contents of the film forming steps A to D will be sequentially described below.

[Case where Film Forming Step a is Selected]

In this case, the following steps 1A to 3A are sequentially performed.

### [Step 1A]

In this step, a TCDMDS gas is supplied to the wafers 200 in the process chamber 201.

Specifically, the valve 243a is opened to allow the TCDMDS gas to flow through the gas supply pipe 232a. The TCDMDS gas, a flow rate of which is adjusted by the MFC 241a, is supplied into the process chamber 201 via the nozzle 249a and subsequently, is exhausted through the exhaust pipe 231. At this time, the TCDMDS gas is supplied to the wafers 200. At the same time, the valve 243c is opened to allow a N₂ gas to flow through the gas supply pipe 232c. The N₂ gas, a flow rate of which is adjusted by the MFC 241c, is supplied into the process chamber 201 via the gas supply pipe 232a and the nozzle 249a and subsequently, is exhausted through the exhaust pipe 231. In addition, in order to prevent the TCDMDS gas from infiltrating into the nozzle 249b, the valve 243d is opened to allow the N₂ gas to flow through the gas supply pipe 232d. The N₂ gas is supplied into the process chamber 201 through the gas supply pipe 232b and the nozzle 249b and subsequently, is exhausted through the exhaust pipe 231.

At this time, an internal pressure of the process chamber 201 is set to fall within a range of, e.g., 1 to 2,666 Pa, specifically 67 to 1,333 Pa. A supply flow rate of the TCDMDS gas is set to fall within a range of, e.g., 1 to 2,000 sccm, specifically 10 to 1,000 sccm. A supply flow rate of the N₂ gas supplied from the respective gas supply pipe is set to fall within a range of, e.g., 100 to 10,000 sccm. A time period during which the TCDMDS gas is supplied is set to fall within a range of, e.g., 1 to 120 seconds, specifically 1 to 60 seconds. The temperature of the heater 207 is set such that the temperature of the wafer 200 falls within a range of, e.g., 250 to 800 degrees C., specifically 350 to 700 degrees C., more specifically 450 to 650 degrees C.

If the temperature of the wafer 200 becomes lower than 250 degrees C., the TCDMDS gas is hardly chemisorbed onto the wafer 200, which may make it impossible to obtain a practical deposition rate. This problem may be solved by setting the temperature of the wafer 200 at 250 degrees C. or higher. By setting the temperature of the wafer 200 at 350 degrees C. or higher, further at 450 degrees C. or higher, it is possible to allow the TCDMDS gas to be sufficiently adsorbed onto the wafer 200, which makes it possible to obtain a sufficient deposition rate.

If the temperature of the wafer 200 exceeds 800 degrees C., an excessive gas phase reaction occurs, which may result in deteriorated uniformity of film thickness and difficulty in control thereof. By setting the temperature of the wafer 200 at 800 degrees C. or lower, it is possible to cause a suitable gas phase reaction. This makes it possible to suppress such deterioration in the film thickness uniformity and facilitate the control thereof. Particularly, if the temperature of the wafer 200 is set at 700 degrees C. or lower, further at 650 degrees C. or lower, a surface reaction becomes more dominant than the gas phase reaction. This makes it easy to secure the film thickness uniformity and facilitate the control thereof.

Accordingly, the temperature of the wafer 200 may be set to fall within a range of 250 to 800 degrees C., specifically 350 to 700 degrees C., more specifically 450 to 650 degrees C.

By supplying the TCDMDS gas to the wafer 200 under the aforementioned conditions, a first layer (an initial layer), for example, an Si-containing layer which contains C and Cl and has a thickness of from less than one atomic layer to several atomic layers (from less than one molecular layer to several molecular layers), is formed on the uppermost surface of the wafer 200. The Si-containing layer which contains C and Cl may include a Si layer which contains C and Cl, an adsorption layer of TCDMDS, or both. The Si-containing layer which contains C and Cl may be a layer containing Si—C bonds.

The Si-containing layer which contains C and Cl is a generic name that encompasses a continuous or discontinuous layer containing C and Cl, which is composed of Si, and a Si thin film containing C and Cl, which is formed of the layers overlapping with one another. Si which constitutes the Si layer containing C and Cl includes not only Si whose bond to C or Cl is not completely broken, but also Si whose bond to C or Cl is completely broken.

The adsorption layer of TCDMDS includes not only a continuous adsorption layer composed of TCDMDS molecules but also a discontinuous adsorption layer. The TCDMDS molecules that constitute the adsorption layer of TCDMDS include a molecule in which Si—Cl bonds are partially broken. That is to say, the adsorption layer of TCDMDS may include a physical adsorption layer of TCDMDS, a chemisorption layer of TCDMDS, or both.

In this regard, a layer having a thickness of less than one atomic layer may mean an atomic layer (a molecular layer) that is discontinuously formed. The layer having a thickness of one atomic layer may mean an atomic layer (a molecular layer) that is continuously formed. The Si-containing layer which contains C and Cl may include both a Si layer containing C and Cl and an adsorption layer of TCDMDS. For the sake of convenience, the expressions such as “one atomic layer”, “several atomic layers” and the like will be used for the Si-containing layer which contains C and Cl, and the term “atomic layer” may be synonymous with the term “molecular layer.”

Under a condition in which the TCDMDS gas is autolyzed (or pyrolyzed), Si is deposited on the wafer 200 to form a Si layer containing C and Cl. Under a condition in which the TCDMDS gas is not autolyzed (or pyrolyzed), TCDMDS is adsorbed onto the wafer 200 to form an adsorption layer of TCDMDS. From the viewpoint of increasing a deposition rate, it may be more advantageous to form the Si layer containing C and Cl on the wafer 200 than to form the adsorption layer of TCDMDS on the wafer 200. Hereinafter, for the sake of convenience, the Si-containing layer which contains C and Cl will be sometimes simply referred to as an Si-containing layer which contains C.

If the thickness of the first layer exceeds several atomic layers, a modification effect performed at steps 2A and 3A, which will be described later, is not applied to the entire first layer. In addition, a minimum value of the thickness of the first layer is less than one atomic layer. Accordingly, the thickness of the first layer may be set to fall within a range of less than one atomic layer to several atomic layers. By setting the thickness of the first layer to become one atomic layer or less, namely one atomic layer or less than one atomic layer, it is possible to relatively increase the modification effect at the steps 2A and 3A which will be described later and to shorten the time required for the modification at the steps 2A and 3A. It is also possible to shorten the time required for formation of the first layer at the step 1A. Consequently, it is possible to shorten the process time per one cycle. This makes it possible to shorten the total process time. That is to say, it is possible to increase the deposition rate. Furthermore, by setting the thickness of the first layer to become one atomic layer or less, it is possible to enhance the controllability of the film thickness uniformity.

After the first layer is formed, the valve 243a is closed to stop the supply of the TCDMDS gas. At this time, the interior of the process chamber 201 is evacuated by the vacuum pump 246 with the APC valve 244 opened. Thus, the TCDMDS gas remaining in the process chamber 201, which has not reacted or which has contributed to the formation of the first layer, is discharged from the interior of the process chamber 201. At this time, with the valves 243c and 243d opened, the supply of the N₂ gas into the process chamber 201 is maintained. The N₂ gas acts as a purge gas, which makes it possible to enhance the effect of discharging the gas remaining in the process chamber 201 from the interior of the process chamber 201.

At this time, the gas remaining in the process chamber 201 may not completely be removed. If the gas remaining in the process chamber 201 is small in amount, there is no adverse effect on the subsequent step 2A. In addition, a flow rate of the N₂ gas supplied into the process chamber 201 does not need to be large. For example, approximately the substantially same amount of the N₂ gas as the volume of the reaction tube 203 (the process chamber 201) may be supplied to perform a purging process to such a degree that this has no adverse effect on step 2A. In this way, since the interior of the process chamber 201 is not completely purged, the purge time can be reduced and a throughput can be improved. In addition, the consumption of the N₂ gas can be restricted to a necessary minimal level.

### [Step 2A]

After the step 1A is completed, a NH₃ gas is supplied to the wafers 200 in the process chamber 201, namely the first layers formed on the wafers 200.

At this step, the opening/closing control of the valves 243b to 243d is performed in the same procedure as the opening/closing control of the valves 243a, 243c and 243d performed at the step 1A. The NH₃ gas, a flow rate of which is adjusted by the MFC 241b, is supplied into the process chamber 201 via the nozzle 249b and subsequently, is exhausted through the exhaust pipe 231. At this time, the NH₃ gas is supplied to the wafers 200.

The supply flow rate of the NH₃ gas is set to fall within a range of, e.g., 100 to 10,000 sccm. The internal pressure of the process chamber 201 is set to fall within a range of, e.g., 1 to 4,000 Pa, specifically 1 to 3,000 Pa. By setting the internal pressure of the process chamber 201 to fall within such a relatively high pressure zone, it is possible to thermally activate the NH₃ gas under a non-plasma atmosphere. Such a thermally-activated NH₃ gas makes it possible to generate a relatively soft reaction, which can make nitridation soft, as will be described later. A time period during which the NH₃ gas is supplied to the wafer 200 is set to fall within a range of, e.g., 1 to 120 seconds, specifically 1 to 60 seconds. Other process conditions may be similar to, e.g., the process conditions of step 1A.

At least a portion of the first layer can be modified (nitrided) by supplying the NH₃ gas to the wafer 200 under the above-described conditions. That is to say, at least a portion of N components contained in the NH₃ gas can be added to the first layer to form a Si—N bond in the first layer. When the first layer is modified, a layer containing Si, C and N, namely, a silicon carbonitride layer (SiCN layer), is formed as a second layer on the wafer 200. When the second layer is formed, at least a portion of C components contained in the first layer is retained (held) in the first layer without being desorbed from the first layer. That is to say, when the second layer is formed, at least a portion of Si—C bonds contained in the first layer is held without being cut and is introduced (remains), as it is, in the second layer. In this way, the second layer becomes a layer containing a Si—C bond and a Si—N bond.

The second layer containing the Si—N bond, i.e., N, has lower desorption probability of C, i.e., higher oxidation resistance, than that of the first layer. This is because N added in the second layer acts to prevent cleavage of the Si—C bond contained in the second layer and suppresses desorption of C from the second layer in step 3A to be described later. That is to say, N contained in the second layer acts as a protective (guard) element against attack of an oxidizing gas supplied in step 3A.

When the second layer is formed, impurities such as Cl contained in the first layer constitute a substance in a gaseous state containing at least Cl in the course of a modification reaction and are discharged out of the process chamber 201. That is to say, the impurities such as Cl in the first layer are extracted or desorbed from the first layer, thereby being separated from the first layer. Accordingly, the second layer has fewer impurities such as Cl than the first layer.

### [Step 3A]

After the step 2A is completed, an O₂ gas is supplied to the wafers 200 in the process chamber 201, namely the second layers formed on the wafers 200.

At this step, the opening/closing control of the valves 243b to 243d is performed in the same procedure as the opening/closing control of the valves 243a, 243c and 243d performed at step 1A. The O₂ gas, a flow rate of which is adjusted by the MFC 241b, is supplied into the process chamber 201 via the nozzle 249b and subsequently, is exhausted through the exhaust pipe 231. At this time, the O₂ gas is supplied to the wafers 200.

The supply flow rate of the O₂ gas is set to fall within a range of, e.g., 1,000 to 10,000 sccm. The internal pressure of the process chamber 201 is set to fall within a range of, e.g., 1 to 4,000 Pa, specifically 1 to 3,000 Pa. By setting the internal pressure of the process chamber 201 to fall within such a relatively high pressure zone, it is possible to thermally activate the O₂ gas under a non-plasma atmosphere. Such a thermally-activated O₂ gas makes it possible to generate a relatively soft reaction, which can make oxidation soft, as will be described later. A time period during which the O₂ gas is supplied is set to fall within a range of, e.g., 1 to 120 seconds, specifically 1 to 60 seconds. Other process conditions may be similar to, e.g., the process conditions of the step 1A

At least a portion of the second layer can be modified (oxidized) by supplying the O₂ gas to the wafer 200 under the above-described conditions. That is to say, at least a portion of O components contained in the O₂ gas can be added to the second layer to form Si—O bonds in the second layer. When the second layer is modified, a layer containing Si, O, C and N, namely, a silicon oxycarbonitride layer (SiOCN layer), is formed as a third layer on the wafer 200. When the third layer is formed, at least a portion of the Si—C bonds contained in the second layer is held without being cut and is introduced (remains), as it is, into the third layer. This is because, as described above, N added in the second layer acts as the guard element for suppressing the desorption of C from the second layer by performing step 2A. When the third layer is formed, at least one of the Si—C bonds contained in the second layer is held without being cut and is introduced (remains), as it is, into the third layer. In this way, the third layer becomes a layer containing Si—O bands, Si—C bonds and Si—N bonds.

When the third layer is formed, impurities such as Cl contained in the second layer are desorbed from the second layer in the same manner as in the above-described step 2A.

### (Performing Cycle Predetermined Number of Times)

A cycle which includes the above-described steps 1A to 3A in this order is performed a predetermined number of times (n₁ times) to thereby form a SiOCN film having a desired composition on the wafer 200. The above cycle may be repeated multiple times. That is to say, a thickness of the third layer formed per one cycle may be set to be smaller than a desired film thickness. Thus, the above cycle may be repeated multiple times until the film thickness of a film formed by laminating the third layers becomes equal to the desired film thickness.

The film formed in the film forming step A tends to have a concentration of C in the film which is not less than a concentration of N in the film (CN). The film formed in the film forming step A tends to have a concentration of C higher than that of a film formed in each of film forming steps B and D (to be described later), and a concentration of C lower than that of a film formed in a film forming step C (to be described later).

[Case where Film Forming Step B is Selected]

In this case, the following steps 1B to 3B are sequentially performed.

### [Step 1B]

In this step, a TCDMDS gas is supplied to the wafer 200 in the process chamber 201. This step has the same process procedure and process conditions as the above-described step 1A. As a result, a first layer (a Si layer containing C and Cl or an adsorption layer of TCDMDS) is formed on the wafer 200. As described above, the first layer is a layer containing Si—C bonds.

### [Step 2B]

After the step 1B is completed, an O₂ gas is supplied to the wafer 200 in the process chamber 201, namely the first layer formed on the wafer 200. This step has the same process procedure and process conditions as the above-described step 3A.

At least a portion of the first layer can be modified (oxidized) by supplying the O₂ gas to the wafer 200 under the above-described conditions. That is to say, at least a portion of O components contained in the O₂ gas can be added to the first layer to form Si—O bonds in the first layer. In addition, at this time, Si—C bonds contained in the first layer can be efficiently cleaved to desorb a large quantity of C atoms from the first layer. Unlike the second layer formed in the above-described step 2A, since N components as guard elements for suppressing desorption of C does not exist in the first layer formed in the step 1B, the desorption of C from the first layer occurs at a higher probability than that in the above-described step 3A. In other words, the first layer formed in the step 1B has a lower oxidation resistance than that of the second layer formed in the step 2A.

By modifying the first layer, a layer containing Si and O and a very small amount of C, namely, a silicon oxide layer (SiO layer) containing a very small amount of C, is formed as the second layer on the wafer 200. In addition, in this step, by desorbing most of C atoms contained in the first layer, it is also possible to reduce the C atoms contained in the first layer to an impurity level. In this case, a layer containing Si and O and not containing C, namely, a C-free SiO layer, is formed as the second layer on the wafer 200. When the second layer is formed, impurities such as Cl and the like contained in the first layer are desorbed from the first layer in the same manner as in the above-described step 2A.

### [Step 3B]

After the step 2B is completed, a NH₃ gas is supplied to the wafer 200 in the process chamber 201, namely the second layer formed on the wafer 200. This step has the same process procedure and process conditions as the above-described step 2A.

At least a portion of the second layer can be modified (nitrided) by supplying the NH₃ gas to the wafer 200 under the above-described conditions. That is to say, at least a portion of N components contained in the NH₃ gas can be added to the second layer to form Si—N bonds in the second layer. When the second layer is modified, a layer containing Si, O and N and a very small amount of C, namely, a SiON layer containing a very small amount of C or a C-free SiON layer, is formed as the third layer on the wafer 200. In this way, the third layer becomes a layer containing Si—O bonds and Si—N bonds, or a layer containing further a very small quality of Si—C bonds. When the third layer is formed, impurities such as Cl and the like contained in the second layer are desorbed from the second layer in the same manner as in the above-described step 2A.

### (Performing Cycle Predetermined Number of Times)

A cycle which includes the above-described steps 1B to 3B in this order is performed a predetermined number of times (n₂ times) to thereby form a film having a desired composition, i.e., a SiON film containing a very small quantity of C or a C-free SiON film, on the wafer 200. The above cycle may be repeated multiple times in the same manner as in the film forming step A.

The film formed in the film forming step B tends to have a concentration of C in the film which is less than a concentration of N in the film (C<N). The film formed in the film forming step B tends to have a concentration of C lower than that of the film formed in the film forming step A, and a concentration of C lower than that of a film formed in each of the film forming steps C and D to be described later.

[Case where Film Forming Step C is Selected]

In this case, steps 1C to 3C are sequentially performed. The steps 1C to 3C have the same process procedure and process conditions as the above-described steps 1A to 3A except that a DCTMDS gas is used as a precursor gas (second precursor gas). A cycle which includes the steps 1C to 3C in this order can be performed a predetermined number of times (n₃ times) to thereby form a SiOCN film having a desired composition on the wafer 200.

The film formed in the film forming step C tends to have a concentration of C in the film which is higher than a concentration of N in the film (C>N). This is because the DCTMDS gas contains Si—C bonds more than the Si—C bonds contained in the TCDMDS gas. Therefore, the film formed using the DCTMDS gas tends to have a concentration of C which is higher than that of the film formed using the TCDMDS gas. The film formed in the film forming step C tends to have a concentration of C higher than that of the film formed in each of in the film forming steps A, B and D.

[Case where Film Forming Step D is Selected]

In this case, steps 1D to 3D are sequentially performed. The steps 1D to 3D have the same process procedure and process conditions as the above-described steps 1B to 3B except that a DCTMDS gas is used as a precursor gas (second precursor gas). A cycle which includes the steps 1D to 3D in this order can be performed a predetermined number of times (n₄ times) to thereby form a SiON film containing a small quantity of C on the wafer 200

The film formed in the film forming step D tends to have a concentration of C in the film which is not higher than a concentration of N in the film (CN). As described above, the film formed using the DCTMDS gas tends to have a concentration of C which is higher than that of the film formed using the TCDMDS gas. Therefore, the film formed in the film forming step D tends to have a concentration of C which is higher than that of the film formed in the film forming step B. However, when performing step 2D of supplying the oxidizing gas, since N as a guard element does not exist in the first layer to be modified, desorption of C from the first layer occurs at a high probability in the step 2D. Therefore, the film formed in the film forming step D tends to have a concentration of C which is lower than that of the film formed in each of the film forming steps A and C.

As described above, by selectively performing any of the film forming steps A to D, it is possible to form a film having a desired composition on the wafer 200. The tendency of the concentration of C in each film is as described above and it is easy to increase the concentration of C in the order of the films formed in the film forming steps B, D, A and C (the concentration of C in the film formed in the film forming step B is the lowest and the concentration of C in the film formed in the film forming step C is the highest).

In any of the film forming steps A to D, in addition to the TCDMDS gas and the DCTMDS gas, an alkylhalosilane precursor gas such as a MCPMDS gas may be used as the first and second precursor gases. However, a gas which contains Si—C bonds more than those contained in the first precursor gas is used as the second precursor gas. That is to say, when the TCDMDS gas is used as the first precursor gas, the DCTMDS gas or the MCPMDS gas is used as the second precursor gas. When the DCTMDS gas is used as the first precursor gas, the MCPMDS gas is used as the second precursor gas. By selecting the types of the first and second precursor gases thus, it is possible to control the composition of a film to be formed on the wafer 200 as described above.

In any of the film forming steps A to D, in addition to the NH₃ gas, a hydronitrogen-based gas such as a diazene (N₂H₂) gas, hydrazine (N₂H₄) gas or N₃H₈ gas may be used as the nitriding gas. Besides these, a gas containing amine, namely an amine-based gas, may be used as the nitriding gas. Examples of the amine-based gas may include a monomethylamine (CH₃NH₂, abbreviation: MMA) gas, dimethylamine ((CH₃)₂NH, abbreviation: DMA) gas, trimethylamine ((CH₃)₃N, abbreviation: TMA) gas, monoethylamine (C₂H₅NH₂, abbreviation: MEA) gas, diethylamine ((C₂H₅)₂NH, abbreviation: DEA) gas, triethylamine ((C₂H₅)₃N, abbreviation: TEA) gas and the like. In addition, a gas containing an organic hydrazine compound, namely an organic hydrazine-based gas may be used as the nitriding gas. Examples of the organic hydrazine-based gas may include a monomethylhydrazine ((CH₃)HN₂H₂, abbreviation: MMH) gas, dimethylhydrazine ((CH₃)₂N₂H₂, abbreviation: DMH) gas, trimethylhydrazine ((CH₃)₂N₂(CH₃)H, abbreviation: TMH) gas and the like.

In addition, in any of the film forming steps A to D, as the oxidizing gas, in addition to the O₂ gas, it may be possible to use water vapor (H₂O gas), nitric monoxide (NO) gas, nitrous oxide (N₂O) gas, nitrogen dioxide (NO₂) gas, carbon monoxide (CO) gas, carbon dioxide (CO₂) gas, ozone (O₃) gas, a mixture of hydrogen (H₂) gas and O₂ gas, a mixture of H₂ gas and O₃ gas, or the like.

In addition, in any of the film forming steps A to D, as the inert gas, in addition to the N₂ gas, it may be possible to use a nobble gas such as an Ar gas, He gas, Ne gas, Xe gas, or the like.

### (After-Purging Step and Atmospheric Pressure Returning Step)

After a selected film forming step is completed and a film having a desired composition is formed, the valves 243a and 243b are closed to stop the supply of the film forming gas (the TCDMDS gas, the DCTMDS gas, the NH₃ gas or the O₂ gas) into the process chamber 201. In addition, the N₂ gas is supplied into the process chamber 201 from each of the gas supply pipes 232c and 232d, and subsequently, is exhausted through the exhaust pipe 231. The N₂ gas serves as a purge gas. Thus, the interior of the process chamber 201 is purged so that the residual gas and reaction byproducts remaining in the process chamber 201 are removed from the interior of the process chamber 201 (after-purging). Thereafter, the internal atmosphere of the process chamber 201 is substituted with an inert gas (inert gas substituting) and the internal pressure of the process chamber 201 is returned to atmospheric pressure (atmospheric pressure returning).

### (Boat Unloading and Wafer Discharging)

Thereafter, the seal cap 219 is moved down by the boat elevator 115 to open the lower end of the manifold 209. The processed wafers 200 supported by the boat 217 are unloaded from the lower end of the manifold 209 outside of the reaction tube 203 (boat unloading). After the boat unloading, the shutter 219s is moved such that the lower end opening of the manifold 209 is sealed by the shutter 219s through the O-ring 220c (shutter closing). The processed wafers 200 are discharged outside of the reaction tube 203 and then are extracted from the boat 217 (wafer discharging).

### (3) Effects According to the Present Embodiment

According to the present embodiment, one or more effects set forth below may be achieved.

(a) By selectively performing one of the film forming steps A to D, it is possible to form a film having a desired composition on the wafer 200.

For example, by selecting and performing the film forming step A, it is possible to form a film having a concentration of C which is not lower than a concentration of N (C≧N) on the wafer 200. This film tends to have a concentration of C which is higher than that of the film formed in each of the film forming steps B and D, and a concentration of C which is lower than that of the film formed in the film forming step C. In this manner, by appropriately increasing the concentration of C in the film, it is possible to enhance the etching resistance to hydrogen fluoride (HF) or the like more than the films formed in the film forming steps B and D.

In addition, for example, by selecting and performing the film forming step B, it is possible to form a film having a concentration of C which is lower than a concentration of N (C<N) on the wafer 200. This film tends to have a concentration of C which is lower than that of the film formed in each of the film forming steps A, C and D. In this manner, by lowering the concentration of C in the film, it is possible to decrease a dielectric constant (k-value) and increase a leak resistance, compared with the film formed in each of the film forming steps A, C and D. Further, it is possible to enhance an oxidation resistance (ashing resistance), compared with the film formed by each of the film forming steps A, C and D.

In addition, for example, by selecting and performing the film forming step C, it is possible to form a film having a concentration of C which is higher than a concentration of N (C>N) on the wafer 200. This film tends to have a concentration of C which is higher than that of the film formed in each of the film forming steps A, B and D. In this manner, by increasing the concentration of C in the film, it is possible to enhance an etching resistance, compared with the film formed in each of the film forming steps A, B and D.

Further, for example, by selecting and performing the film forming step D, it is possible to form a film having a concentration of C which is not higher than a concentration of N (CN) on the wafer 200. This film tends to have a concentration of C which is lower than that of the film formed in each of the film forming steps A and C, and a concentration of C which is higher than that of the film formed in the film forming step B. In this manner, by appropriately lowering the concentration of C in the film, it is possible to decrease a k-value and enhance a leak resistance, compared with the film formed in each of the film forming steps A and C. Further, by appropriately lowering the concentration of C in the film, it is possible to enhance an ashing resistance, compared with the film formed by each of the film forming steps A and C.

As a result, by selectively performing any one of the film forming steps A to D, it is possible to form a film having a desired composition. The selection of performing any of the film forming steps A to D may be determined depending on characteristics (film applications) required for the respective film. For example, to form a film having high etching resistance requires selecting the film forming step C. In addition, to form a film having a low k-value and high leak resistance or a film having high ashing resistance requires selecting the film forming step B. To form a film having etching resistance, leak resistance and so on in a balanced manner requires selecting one of the film forming steps A and D. From the viewpoint of the balance, the film forming step A may be selected if the etching characteristics are relatively important and the film forming step D may be selected if the leak resistance and the ashing resistance are relatively important.

(b) By using three kinds of gases, i.e., the precursor gas (the TCDMDS gas or the DCTMDS gas), the nitriding gas (the NH₃ gas) and the oxidizing gas (the O₂ gas), the content of four elements Si, O, C and N can be adjusted over a wide range. That is to say, it is unnecessary to separately supply four sources, i.e., a Si source, an O source, a C source and an N source during the film forming process. Therefore, it is possible to shorten the time required per one cycle, thereby further improving the productivity of the film forming process. In addition, by reducing the kinds of gases required for the film forming process, it is possible to simplify the configuration of the gas supply system, thereby reducing equipment costs and the like.

(c) By using a gas having Si—C bonds, such as the TCDMDS gas or the DCTMDS gas, as a precursor gas, it is possible to allow a high concentration of C to be contained in a film finally formed. That is to say, it is possible to allow the high concentration of C to be contained in the film to an unrealizable extent when using a C-free Si source such as a hexachlorodisilane (Si₂Cl₆, abbreviation: HCDS) gas as a precursor gas and using the four sources of Si, O, C and N in the film forming process, thereby extending a window for controlling the concentration of C.

(d) The aforementioned effects can be equally achieved in a case where an organic silane precursor gas other than the TCDMDS gas is used as the first precursor gas, a case where an organic silane precursor gas other than the DCTMDS gas is used as the second precursor gas, a case where an N-containing gas other than the NH₃ gas is used as the nitriding gas and a case where an O-containing gas other than the O₂ gas is used as the oxidizing gas.

### (4) Modifications

The film forming steps in this embodiment may be modified to the following modifications.

### (First Modification)

For example, by selecting at least two of the film forming steps A to D and alternately performing the selected steps n₅ times (n₅ is an integer of one or more), it is possible to form a laminated film, which is obtained by alternately laminating films in which at least one of concentrations of C and N is different from each other.

In this case, as exemplified below, by finally performing the film forming step A, the outermost surface of the laminated film may be a film in which the concentration of C is not lower than the concentration of N (CN).

([b]→[a])×n₅

([c]→[a])×n₅

([d]→[a])×n₅

([b]→[c]→[a])×n₅

([c]→[b]→[a])×n₅

([b]→[d]→[a])×n₅

([d]→[b]→[a])×n₅

([c]→[d]→[a])×n₅

([d]→[c]→[a])×n₅

In addition, in this case, as exemplified below, by finally performing the film forming step B, the outermost surface of the laminated film may be a film in which the concentration of C is lower than the concentration of N (C<N).

([a]→[b])×n₅

([c]→[b])×n₅

([d]→[b])×n₅

([a]→[c]→[b])×n₅

([c]→[a]→[b])×n₅

([a]→[d]→[b])×n₅

([d]→[a]→[b])×n₅

([c]→[d]→[b])×n₅

([d]→[c]→[b])×n₅

In addition, in this case, as exemplified below, by finally performing the film forming step C, the outermost surface of the laminated film may be a film in which the concentration of C is higher than the concentration of N (C>N).

([a]→[c])×n₅

([b]→[c])×n₅

([d]→[c])×n₅

([a]→[b]→[c])×n₅

([b]→[a]→[c])×n₅

([a]→[d]→[c])×n₅

([d]→[a]→[c])×n₅

([b]→[d]→[c])×n₅

([d]→[b]→[c])×n₅

In addition, in this case, as exemplified below, by finally performing the film forming step D, the outermost surface of the laminated film may be a film in which the concentration of C is not higher than the concentration of N (CN).

([a]→[d])×n₅

([b]→[d])×n₅

([c]→[d])×n₅

([a]→[b]→[d])×n₅

([b]→[a]→[d])×n₅

([a]→[c]→[d])×n₅

([c]→[a]→[d])×n₅

([b]→[c]→[d])×n₅

([c]→[b]→[d])×n₅

In addition, by finally performing the film forming step A, the lowermost surface of the laminated film may be a film in which the concentration of C is not lower than the concentration of N (C≧N). Further, by initially performing the film forming step B, the lowermost surface of the laminated film may be a film in which the concentration of C is lower than the concentration of N (C<N). Further, by initially performing the film forming step C, the lowermost surface of the laminated film may be a film in which the concentration of C is higher than the concentration of N (C>N). Further, by initially performing the film forming step D, the lowermost surface of the laminated film may be a film in which the concentration of C is not higher than the concentration of N (C≦N).

In these cases, by setting the film thickness of each film (each film constituting the laminated film) formed in the film forming steps A to D at, e.g., 5 nm or less, specifically 1 nm or less, the laminated film finally formed may be a film having characteristics unified in the thickness direction, namely a nanolaminate film having characteristics integrally inseparable as the entire film. Further, by forming the nanolaminate film, for example, it is possible to form a film having both the etching resistance and the leak resistance which are in a trade-off relationship. By setting the number of repetitions (n₁ to n₄) of the cycle including the film forming steps A to D at about 1 to 10 times, it is possible to set the film thickness of each film constituting the laminated film to fall within the above-mentioned range.

In addition, if the film forming step C is finally performed, at least the outermost surface of the laminated film may be a film having high etching resistance. In addition, if the film forming step B is finally performed, at least the outermost surface of the laminated film may be a film having a low k value and high leak resistance, or a film with high ashing resistance. In addition, if any one of the film forming steps A and D is finally performed, at least the outermost surface of the laminated film may be a film having etching resistance, leak resistance and the like at a balanced level. Further, from the viewpoint of the balance, if the film forming step A is finally performed, at least the outermost surface of the laminated film may be a film having relatively high etching resistance. In addition, if the film forming step D is finally performed, at least the outermost surface of the laminated film may be a film having relatively high leak resistance and ashing resistance. In this way, when the outermost surface or the lowermost surface of the laminated film is formed, by selectively performing one of the film forming steps A to D in an appropriate manner, it is possible to impart desired characteristics to the respective surface.

### (Second Modification)

In the second modification, by adjusting at least one of the number of repetitions (n₁ to n₄) of the cycle including the film forming steps A to D, a gradation of at least one of the concentrations of C and N may be applied in the thickness direction of the laminated film.

For example, the film formation step A and the film formation step B are alternately performed to form a laminated film including a film having the concentration of C not lower than the concentration of N and a film having the concentration of C lower than the concentration of N. At this time, by adjusting at least one of n₁ and n₂, a gradation of at least one of the concentrations of C and N may be applied in the thickness direction of the laminated film. For example, by gradually increasing a ratio of n₁ to n_{z} every time the film forming steps A and B are alternately performed, a gradation in which the concentration of C gradually increases from the lowermost surface toward the outermost surface may be applied in the thickness direction of the laminated film.

In addition, for example, the film formation step A and the film formation step C are alternately performed to form a laminated film including a film having the concentration of C not lower than the concentration of N and a film having the concentration of C higher than the concentration of N. At this time, by adjusting at least one of n₁ and n₃, a gradation of at least one of the concentrations of C and N may be applied in the thickness direction of the laminated film. For example, by gradually increasing a ratio of n₃ to n₁ every time the film forming steps A and C are alternately performed, a gradation in which the concentration of C gradually increases from the lowermost surface toward the outermost surface may be applied in the thickness direction of the laminated film.

In addition, for example, the film formation step A and the film formation step D are alternately performed to form a laminated film including a film having the concentration of C not lower than the concentration of N and a film having the concentration of C not higher than the concentration of N. At this time, by adjusting at least one of n₁ and n₄, a gradation of at least one of the concentrations of C and N may be applied in the thickness direction of the laminated film. For example, by gradually increasing a ratio of n₁ to n₄ every time the film forming steps A and D are alternately performed, a gradation in which the concentration of C gradually increases from the lowermost surface toward the outermost surface may be applied in the thickness direction of the laminated film.

In addition, for example, the film formation step B and the film formation step C are alternately performed to form a laminated film including a film having the concentration of C lower than the concentration of N and a film having the concentration of C higher than the concentration of N. At this time, by adjusting at least one of n₂ and n₃, a gradation of at least one of the concentrations of C and N may be applied in the thickness direction of the laminated film. For example, by gradually increasing a ratio of n₃ to n_{z} every time the film forming steps B and C are alternately performed, a gradation in which the concentration of C gradually increases from the lowermost surface toward the outermost surface may be applied in the thickness direction of the laminated film.

In addition, for example, the film formation step B and the film formation step D are alternately performed to form a laminated film including a film having the concentration of C lower than the concentration of N and a film having the concentration of C not higher than the concentration of N. At this time, by adjusting at least one of n₂ and n₄, a gradation of at least one of the concentrations of C and N may be applied in the thickness direction of the laminated film. For example, by gradually increasing a ratio of n₄ to n_{z} every time the film forming steps B and D are alternately performed, a gradation in which the concentration of C gradually increases from the lowermost surface toward the outermost surface may be applied in the thickness direction of the laminated film.

In addition, for example, the film formation step C and the film formation step D are alternately performed to form a laminated film including a film having the concentration of C higher than the concentration of N and a film having the concentration of C not higher than the concentration of N. At this time, by adjusting at least one of n₃ and n₄, a gradation of at least one of the concentrations of C and N may be applied in the thickness direction of the laminated film. For example, by gradually increasing a ratio of n₃ to n₄ every time the film forming steps C and D are alternately performed, a gradation in which the concentration of C gradually increases from the lowermost surface toward the outermost surface may be applied in the thickness direction of the laminated film.

### (Third Modification)

As the first and second source gases, an alkylenehalosilane precursor gas such as a BTCSM gas or a BTCSE gas may be used. A step of supplying the alkylenehalosilane precursor gas has the same process procedure and process conditions as the steps 1A to 1D in the film forming sequence shown in FIGS. 4A to 4D. This modification achieves the same effects as the film formation sequence shown in FIGS. 4A to 4D. For example, by using the BTCSM gas as the first precursor gas and the BTCSE gas which contains C more than that contained in the BTCSM gas as the second precursor gas, it is easy to increase the concentration of C in the films formed in the film forming steps B, D, A and C in this order (the concentration of C in the film formed in the film forming step B is the lowest and the concentration of C in the film formed in the film forming step C is the highest).

In addition, unlike the alkylhalosilane precursor gas such as the TCDMDS gas, the alkylenehalosilane precursor gas such as the BTCSM gas contains C which is not in the form of Si—C bonds but in the form of Si—C—Si bonds or Si—C—C—Si bonds. Due to such a difference in the form, a layer formed using the alkylenehalosilane precursor gas as the precursor gas has a relatively low probability that C is completely cut from Si or the like when an oxidizing gas or a nitriding gas is supplied, compared with a layer formed using the alkylhalosilane precursor gas as the precursor gas. Therefore, the layer formed using the alkylenehalosilane precursor gas tends to have a relatively low probability in the desorption of C. That is to say, a the film formed using the alkylenehalosilane precursor gas as the precursor gas tends to have a relatively high concentration of C, compared with the film formed using the alkylhalosilane precursor gas as the precursor gas. This point may be reflected in selecting the first and second precursor gases.

### Other Embodiments

While some embodiments of the present disclosure have been specifically described above, the present disclosure is not limited to the aforementioned embodiments but may be differently modified without departing from the subject matter of the present disclosure.

The present disclosure can be appropriately applied to a case of forming a film containing a metal element such as titanium (Ti), zirconium (Zr), hafnium (Hf), tantalum (Ta), niobium (Nb), molybdenum (Mo), tungsten (W), yttrium (Y), strontium (Sr), lanthanum (La), ruthenium (Ru), aluminum (Al) or the like on the wafer 200. That is to say, the present disclosure can be appropriately applied to a case of forming a metal oxycarbonitride film such as a TiOCN film, ZrOCN film, HfOCN film, TaOCN film, NbOCN film, MoOCN film, WOCN film, YOCN film, SrOCN film, LaOCN film, RuOCN film, AlOCN film or the like, or a case of forming a metal oxynitride film such as a TiON film, ZrON film, HfON film, TaON film, NbON film, MoON film, WON film, YON film, SrON film, LaON film, RuON film, AlON film or the like.

Process procedure and process conditions of a film forming process in these cases may be the same as those in the aforementioned embodiments and modifications. These cases achieve the same effects as those of the aforementioned embodiments and modifications.

Recipes (programs describing process procedures and process conditions) used in a substrate process may be prepared individually according to the process contents (the kind, composition ratio, quality, film thickness, process procedure, process condition and so on of a film to be formed) and may be stored in the memory device 121c via a telecommunication line or the external memory device 123. Moreover, at the start of the substrate process, the CPU 121a may properly select an appropriate recipe from the recipes stored in the memory device 121c according to the process contents. Thus, it is possible for a single substrate processing apparatus to form films of different kinds, composition ratios, qualities and thicknesses with enhanced reproducibility. In addition, it is possible to reduce an operator's burden (e.g., a burden borne by an operator when inputting process procedures and process conditions) and to quickly start the substrate process while avoiding an operation error.

The recipes mentioned above are not limited to newly-prepared ones but may be prepared by, for example, modifying the existing recipes already installed in the substrate processing apparatus. When modifying the recipes, the modified recipes may be installed in the substrate processing apparatus via a telecommunication line or a recording medium storing the recipes. In addition, the existing recipes already installed in the substrate processing apparatus may be directly modified by operating the input/output device 122 of the substrate processing apparatus.

In the aforementioned embodiments, there has been described an example in which films are formed using a batch-type substrate processing apparatus capable of processing a plurality of substrates at a time. The present disclosure is not limited to the aforementioned embodiments but may be appropriately applied to, e.g., a case where films are formed using a single-wafer-type substrate processing apparatus capable of processing a single substrate or several substrates at a time. In addition, in the aforementioned embodiments, there has been described an example in which films are formed using a substrate processing apparatus provided with a hot-wall-type processing furnace. The present disclosure is not limited to the aforementioned embodiments but may be appropriately applied to a case where films are formed using a substrate processing apparatus provided with a cold-wall-type processing furnace.

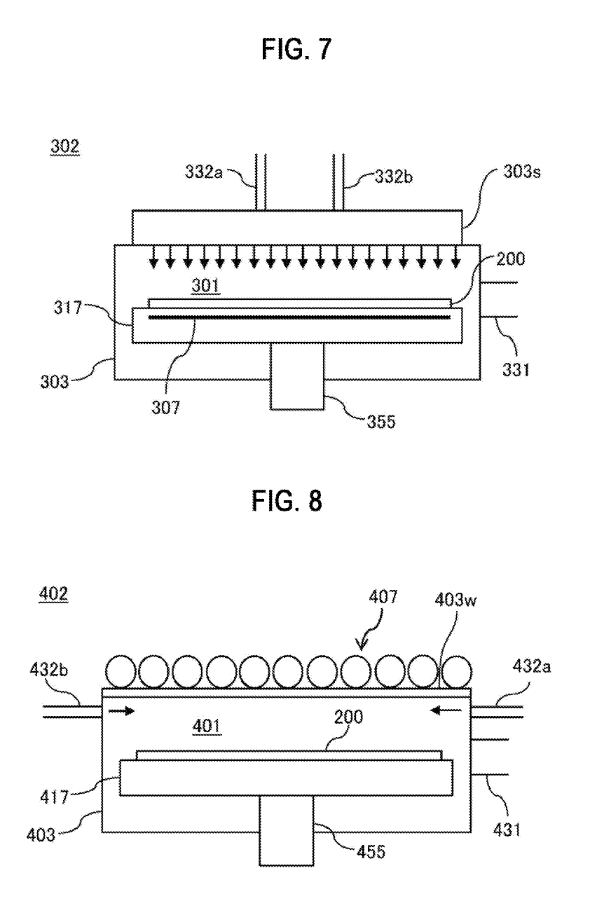

The present disclosure may be suitably applied to, e.g., a case where a film is formed using a substrate processing apparatus provided with a processing furnace 302 illustrated in FIG. 7. The processing furnace 302 includes a process vessel 303 which defines a process chamber 301, a shower head 303s as a gas supply part configured to supply a gas into the process chamber 301 in a shower-like manner, a support table 317 configured to horizontally support one or more wafers 200, a rotary shaft 355 configured to support the support table 317 from below, and a heater 307 installed in the support table 317. Gas supply ports 332a and 332b are connected to inlets (gas introduction holes) of the shower head 303s. A supply system similar to the precursor gas supply system of the aforementioned embodiments is connected to the gas supply port 332a. A supply system similar to the nitriding gas supply system and the oxidizing gas supply system of the aforementioned embodiments is connected to the gas supply port 332b. A gas distribution plate configured to supply a gas into the process chamber 301 in a shower-like manner is installed in outlets (gas discharge holes) of the shower head 303s. The shower head 303s is installed at such a position as to face the surfaces of the wafers 200 loaded into the process chamber 301. An exhaust port 331 through which the interior of the process chamber 301 is exhausted is installed in the process vessel 303. An exhaust system similar to the exhaust systems of the aforementioned embodiments is connected to the exhaust port 331.

In addition, the present disclosure may be suitably applied to, e.g., a case where a film is formed using a substrate processing apparatus provided with a processing furnace 402 illustrated in FIG. 8. The processing furnace 402 includes a process vessel 403 which defines a process chamber 401, a support table 417 configured to horizontally support one or more wafers 200, a rotary shaft 455 configured to support the support table 417 from below, a lamp heater 407 configured to emit light toward the wafers 200 disposed in the process vessel 403, and a quartz window 403w which allows the light emitted from the lamp heater 407 to transmit therethrough. Gas supply ports 432a and 432b are connected to the process vessel 403. A supply system similar to the precursor gas supply system of the aforementioned embodiments is connected to the gas supply port 432a. A supply system similar to the nitriding gas supply system and the oxidizing gas supply system of the aforementioned embodiments is connected to the gas supply port 432b. The gas supply ports 432a and 432b are respectively installed at the lateral side of the end portions of the wafers 200 loaded into the process chamber 401, namely at such positions as not to face the surfaces of the wafers 200 loaded into the process chamber 401. An exhaust port 431 through which the interior of the process chamber 401 is exhausted is installed in the process vessel 403. An exhaust system similar to the exhaust system of the aforementioned embodiments is connected to the exhaust port 431.

Even in the case of using these substrate processing apparatuses, a film forming process may be performed according to the same process procedures and process conditions as those in the aforementioned embodiments and modifications, and the same effects as those of the aforementioned embodiments and modifications can be achieved.

The aforementioned embodiments and modifications may be used in proper combination. Process procedures and process conditions used at this time may be the same as those of the aforementioned embodiments.

### Examples

As Examples 1 to 3, the substrate processing apparatus of the above embodiments was used to form films on wafers by selectively performing the film forming steps A, B and C respectively. A TCDMDS gas, a DCTMDS gas, a NH₃ gas and an O₂ gas were used as a first precursor gas, a second precursor gas, a nitriding gas and an oxidizing gas, respectively. Process conditions in respective gas supply steps are conditions within the process condition range described in the above embodiments and are set in common in Examples 1 to 3.

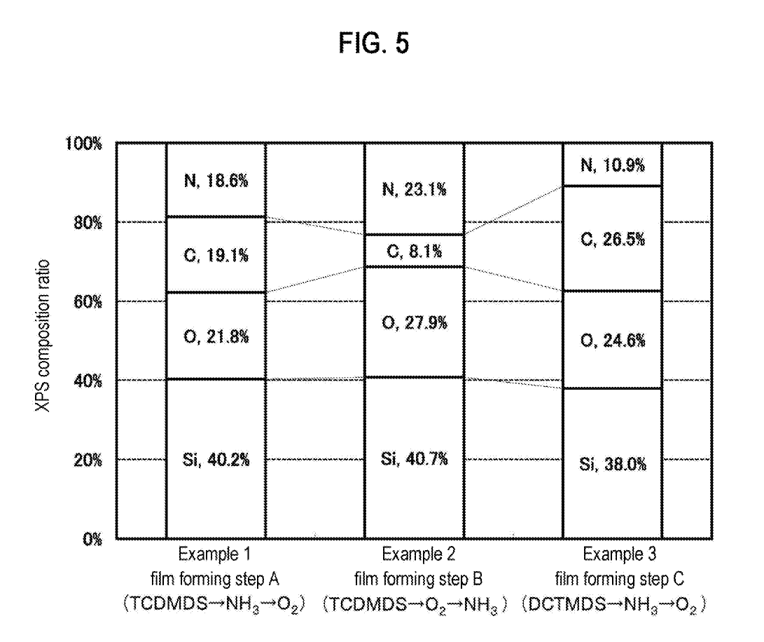

Then, concentrations of Si, O, C and N contained in each of the films formed in Examples 1 to 3 were measured by XPS (X-ray Photoelectron Spectroscopy). The results are shown in FIG. 5. In FIG. 5, a horizontal axis represents Examples 1, 2 and 3 and a vertical axis represents the concentration (at %) of each element in the film. As can be seen from FIG. 5, in Example 1, a film having a concentration of C not lower than a concentration of N (C≧N) was formed on a wafer by selecting and performing the film forming step A. In addition, in Example 2, a film having a concentration of C lower than a concentration of N (C<N) was formed on a wafer by selecting and performing the film forming step B. In addition, in Example 3, a film having a concentration of C higher than a concentration of N (C>N) was formed on a wafer by selecting and performing the film forming step C.

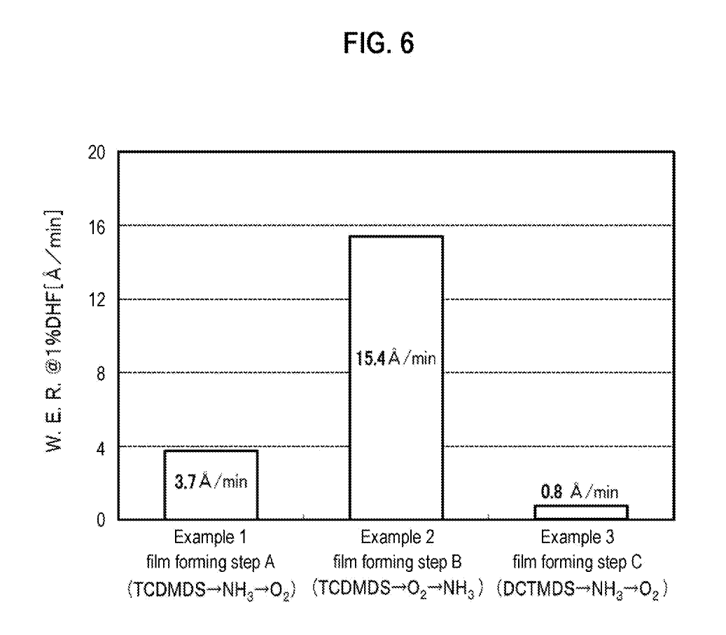

In addition, etching resistance of each of the films formed in Examples 1 to 3 was measured. The results are shown in FIG. 6. In FIG. 6, a horizontal axis represents Examples 1, 2 and 3 and a vertical axis represents an wet etching rate (W.E.R.) [Å/min] when a film is etched using a HF-containing solution with a concentration of 1%, namely the resistance of the film to HF. As can be seen from FIG. 6, the films having a relatively high concentration of C as in Examples 1 and 3 have higher etching resistance (smaller W.E.R.) than that of the film having a relatively low concentration of C as in Example 2. Further, in Examples 1 and 3, in spite of the supply of the precursor gas, the nitriding gas and the oxidizing gas in this order, it can be seen that the film of Example 3 using the DCTMDS gas as the precursor gas has higher etching resistance than that of the film of Example 1 using the TCDMDS gas as the precursor gas.

According to the present disclosure in some embodiments, it is possible to improve the controllability of a composition ratio of a film formed on a substrate.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of manufacturing a semiconductor device, comprising:
forming a film having a desired composition on a substrate by selectively performing at least one of:
(a) performing a cycle, n₁ times (n₁ being an integer of one or more), the cycle including performing in the following order: supplying a first precursor gas containing a chemical bond of a predetermined element and carbon to the substrate, supplying a nitriding gas to the substrate, and supplying an oxidizing gas to the substrate;
(b) performing a cycle, n₂ times (n₂ being an integer of one or more), the cycle including performing in the following order: supplying the first precursor gas to the substrate, supplying an oxidizing gas to the substrate, and supplying a nitriding gas to the substrate;
(c) performing a cycle, n₃ times (n₃ being an integer of one or more), the cycle including performing in the following order: supplying a second precursor gas containing a chemical bond of the predetermined element and carbon, which is more than the chemical bond of the predetermined element and carbon contained in the first precursor gas, to the substrate, supplying a nitriding gas to the substrate, and supplying an oxidizing gas to the substrate; and
(d) performing a cycle, n₄ times (n₄ being an integer of one or more), the cycle including performing in the following order: supplying the second precursor gas to the substrate, supplying an oxidizing gas to the substrate, and supplying a nitriding gas to the substrate.

2. The method of claim 1, comprising:
forming a laminated film, which is obtained by alternately laminating films in which at least one of a concentration of carbon and a concentration of nitrogen is different from each other, by selecting at least two of the acts (a), (b), (c) and (d) and alternately performing the selected at least two acts, n₅ times (n₅ being an integer of one or more).

3. The method of claim 2, comprising:
forming an outermost surface of the laminated film as a film having the concentration of carbon not lower than the concentration of nitrogen by finally performing the act (a).

4. The method of claim 2, comprising:
forming an outermost surface of the laminated film as a film having the concentration of carbon lower than the concentration of nitrogen by finally performing the act (b).

5. The method of claim 2, comprising:
forming an outermost surface of the laminated film as a film having the concentration of carbon higher than the concentration of nitrogen by finally performing the act (c).

6. The method of claim 2, comprising:
forming an outermost surface of the laminated film as a film having the concentration of carbon not higher than the concentration of nitrogen by finally performing the act (d).

7. The method of claim 2, wherein the laminated film is formed by a film having the concentration of carbon not lower than the concentration of nitrogen and a film having the concentration of carbon lower than the concentration of nitrogen by alternately performing the acts (a) and (b).

8. The method of claim 2, wherein the laminated film is formed by a film having the concentration of carbon not lower than the concentration of nitrogen and a film having the concentration of carbon higher than the concentration of nitrogen by alternately performing the acts (a) and (c).

9. The method of claim 2, wherein the laminated film is formed by a film having the concentration of carbon not lower than the concentration of nitrogen and a film having the concentration of carbon not higher than the concentration of nitrogen by alternately performing the acts (a) and (d).

10. The method of claim 2, wherein the laminated film is formed by a film having the concentration of carbon lower than the concentration of nitrogen and a film having the concentration of carbon higher than the concentration of nitrogen by alternately performing the acts (b) and (c).

11. The method of claim 2, wherein the laminated film is formed by a film having the concentration of carbon lower than the concentration of nitrogen and a film having the concentration of carbon not higher than the concentration of nitrogen by alternately performing the acts (b) and (d).

12. The method of claim 2, wherein the laminated film is formed by a film having the concentration of carbon higher than the concentration of nitrogen and a film having the concentration of carbon not higher than the concentration of nitrogen by alternately performing the acts (c) and (d).

13. The method of claim 1, wherein a film having a concentration of carbon not lower than a concentration of nitrogen is formed by selectively performing the act (a).

14. The method of claim 1, wherein a film having a concentration of carbon lower than a concentration of nitrogen is formed by selectively performing the act (b).

15. The method of claim 1, wherein a film having a concentration of carbon higher than a concentration of nitrogen is formed by selectively performing the act (c).

16. The method of claim 1, wherein a film having a concentration of carbon not higher than a concentration of nitrogen is formed by selectively performing the act (d).

17. The method of claim 1, further comprising:
providing a program for executing a procedure of the act (a), a program for executing a procedure of the act (b), a program for executing a procedure of the act (c), and a program for executing a procedure of the act (d); and
selectively executing at least one of the programs.

18. The method of claim 1, wherein each of the first precursor gas and the second precursor gas contains carbon-containing ligands, and the number of the carbon-containing ligands contained in the second precursor gas is larger than the number of the carbon-containing ligands contained in the first precursor gas.

19. A substrate processing apparatus, comprising:
a process chamber in which a substrate is accommodated;
a precursor gas supply system configured to supply a first precursor gas containing a chemical bond of a predetermined element and carbon, or a second precursor gas containing a chemical bond of the predetermined element and carbon which is more than the chemical bond of the predetermined element and carbon contained in the first precursor gas, to the substrate in the process chamber;
a nitriding gas supply system configured to supply a nitriding gas to the substrate in the process chamber;
an oxidizing gas supply system configured to supply an oxidizing gas to the substrate in the process chamber; and
a control part configured to control the precursor gas supply system, the nitriding gas supply system and the oxidizing gas supply system so as to form a film having a desired composition on the substrate by selectively performing at least one of:
(a) performing a cycle, n₁ times (n₁ being an integer of one or more), the cycle including performing in the following order: supplying the first precursor gas to the substrate, supplying the nitriding gas to the substrate, and supplying the oxidizing gas to the substrate;
(b) performing a cycle, n₂ times (n₂ being an integer of one or more), the cycle including performing in the following order: supplying the first precursor gas to the substrate, supplying the oxidizing gas to the substrate, and supplying the nitriding gas to the substrate;
(c) performing a cycle, n₃ times (n₃ being an integer of one or more), the cycle including performing in the following order: supplying the second precursor gas to the substrate, supplying the nitriding gas to the substrate, and supplying the oxidizing gas to the substrate; and
(d) performing a cycle, n₄ times (n₄ being an integer of one or more), the cycle including performing in the following order: supplying the second precursor gas to the substrate, supplying the oxidizing gas to the substrate, and supplying the nitriding gas to the substrate.

20. A non-transitory computer-readable recording medium storing a program that causes a computer to perform a process of forming a film having a desired composition on a substrate by selectively performing at least one of:
(a) performing a cycle, n₁ times (n₁ being an integer of one or more), the cycle including performing in the following order: supplying a first precursor gas containing a chemical bond of a predetermined element and carbon to the substrate, supplying a nitriding gas to the substrate, and supplying an oxidizing gas to the substrate;
(b) performing a cycle, n₂ times (n₂ being an integer of one or more), the cycle including performing in the following order: supplying the first precursor gas to the substrate, supplying an oxidizing gas to the substrate, and supplying a nitriding gas to the substrate;
(c) performing a cycle, n₃ times (n₃ being an integer of one or more), the cycle including performing in the following order: supplying a second precursor gas containing a chemical bond of the predetermined element and carbon, which is more than the chemical bond of the predetermined element and carbon contained in the first precursor gas, to the substrate, supplying a nitriding gas to the substrate, and supplying an oxidizing gas to the substrate; and
(d) performing a cycle, n₄ times (n₄ being an integer of one or more), the cycle including performing in the following order: supplying the second precursor gas to the substrate, supplying an oxidizing gas to the substrate, and supplying a nitriding gas to the substrate.
